(19) United States
(12) Patent Application Publication
(10) Pub. No.: US 2026/0317589 A1
(43) Pub. Date: Oct. 15, 2026

(54) FILM ADHESIVE, DICING AND DIE-BONDING TWO-IN-ONE FILM, SEMICONDUCTOR DEVICE, AND MANUFACTURING METHOD FOR SAME

(71) Applicant: Resonac Corporation, Minato-ku, Tokyo (JP)

(72) Inventors: Keita HOSONO, Tokyo (JP); Tomoyo KANEKO, Tokyo (JP)

(21) Appl. No.: 19/476,183

(22) PCT Filed: Oct. 20, 2023
(86) PCT No.: PCT/JP2023/038091

§ 371 Date: Oct. 17, 2025

(51) Int. Cl. C09J 7/38; C09J 5/00; H10P 58/00; H10P 72/70; H10W 72/00; H10W 90/00

(52) U.S. Cl. CPC C09J 7/38; C09J 5/00; H10P 58/00; H10P 72/7402; H10W 72/073; H10W 90/732; H10W 90/734; C09J 2203/326; C09J 2301/302; C09J 2301/416

(57) ABSTRACT

A film-shaped adhesive contains an epoxy resin, a phenolic resin, and an elastomer, and may further contain an inorganic filler. A content of the inorganic filler is from 0 to 5% by mass based on a total amount of the film-shaped adhesive. A storage modulus of the film-shaped adhesive at 25° C. is 1200 MPa or more.

### TECHNICAL FIELD

The present disclosure relates to a film-shaped adhesive, a dicing/die-bonding integrated film, a semiconductor device, and a method for manufacturing the same.

### BACKGROUND ART

In recent years, stacked MCPs (Multi Chip Packages) in which semiconductor chips are stacked in multiple stages have become widespread, and are mounted as memory semiconductor packages for mobile phones, portable audio devices, and the like. Furthermore, with the multi-functionalization of mobile phones and the like, higher speeds, higher densities, and higher integration of semiconductor packages are also being promoted.

As a method for manufacturing a semiconductor device (semiconductor package), a method is known for producing a plurality of singulated semiconductor chips with an adhesive piece. This method involves laminating a dicing/die-bonding integrated film, which includes an adhesive layer disposed on the pressure-sensitive adhesive layer of a dicing film, onto the back surface of a semiconductor wafer, and then dicing and singulating a part of the semiconductor wafer, the adhesive layer, and the pressure-sensitive adhesive layer. For example, Patent Literatures 1 and 2 disclose a film-shaped adhesive used as an adhesive layer in such a method.

### CITATION LIST

### Patent Literature

Patent Literature 1: WO 2013/133275 A1
Patent Literature 2: WO 2020/013250 A1

### SUMMARY OF INVENTION

### Technical Problem

By using a semiconductor chip with an adhesive piece, the semiconductor chip and a support member are bonded via the adhesive piece. By the way, in recent semiconductor devices (semiconductor packages), in semiconductor chips composed of a circuit layer and a semiconductor layer, there is a trend for the circuit layer to become thicker and the semiconductor layer to become thinner. In such semiconductor chips, for example, chip cracks may occur when picking up the semiconductor chip with an adhesive piece from the pressure-sensitive adhesive layer of the dicing film. It is presumed that such chip cracks occur because the semiconductor layer becomes thinner, making the semiconductor chip brittle, and are caused by vibrations during pickup. Therefore, the film-shaped adhesive used for the dicing/die-bonding integrated film is required to be able to suppress the occurrence of chip cracks.

Therefore, a main object of the present disclosure is to provide a film-shaped adhesive that exhibits excellent peelability from the pressure-sensitive adhesive layer of a dicing film when applied to the adhesive layer of a dicing/die-bonding integrated film.

### Solution to Problem

As a result of diligent studies by the present inventors to solve the above problem, they found that in a film-shaped adhesive containing an epoxy resin, a phenolic resin, and an elastomer, and optionally further containing an inorganic filler, it is possible to reduce the edge peel strength (the peak of peel strength that occurs at the edge of the adhesive layer when peeling the pressure-sensitive adhesive layer of the dicing film from the adhesive layer) between the pressure-sensitive adhesive layer of the dicing film and the adhesive layer by adjusting the storage modulus at 25° C. to a predetermined range, and have thus completed the invention of the present disclosure.

The present disclosure provides the film-shaped adhesive according to [1] to [8], the dicing/die-bonding integrated film according to [9], the semiconductor device according to [10] and [11], and the method for manufacturing a semiconductor device according to [12] to [17].

[1] A film-shaped adhesive containing an epoxy resin, a phenolic resin, and an elastomer, and optionally further containing an inorganic filler, wherein a content of the inorganic filler is from 0 to 5% by mass based on a total amount of the film-shaped adhesive, and a storage modulus at 25° C. is 1200 MPa or more.
[2] The film-shaped adhesive according to [1], wherein a content of the elastomer is from 20 to 50% by mass based on the total amount of the film-shaped adhesive, and a total content of the epoxy resin and the phenolic resin is from 45 to 80% by mass based on the total amount of the film-shaped adhesive.
[3] The film-shaped adhesive according to [1] or [2], wherein the epoxy resin contains a first epoxy resin having a softening point of 40° C. or less, and a content of the first epoxy resin is from 2 to 20% by mass based on the total amount of the film-shaped adhesive.
[4] The film-shaped adhesive according to [3], wherein the epoxy resin further contains a second epoxy resin having a softening point of more than 40° C., and a softening point of the second epoxy resin is 120° C. or less.
[5] The film-shaped adhesive according to any one of [1] to [4], wherein a storage modulus at 150° C. of a cured product obtained by curing the film-shaped adhesive at 150° C. for 30 minutes is 40 MPa or more.
[6] The film-shaped adhesive according to any one of [1] to [5], wherein a thickness of the film-shaped adhesive is from 1 to 15 μm.
[7] The film-shaped adhesive according to any one of [1] to [6], for use in a manufacturing process for a semiconductor device formed by stacking a plurality of semiconductor chips.
[8] The film-shaped adhesive according to [7], wherein the semiconductor device is a 3D NAND memory.
[9] A dicing/die-bonding integrated film, including in this order: a base layer; a pressure-sensitive adhesive layer; and an adhesive layer consisting of the film-shaped adhesive according to any one of [1] to [6].
[10] A semiconductor device, including: a semiconductor chip; a support member on which the semiconductor chip is mounted; and a cured product of the film-shaped adhesive according to any one of [1] to [6], disposed between the semiconductor chip and the support member and bonding the semiconductor chip and the support member.
[11] The semiconductor device according to [10], further including a different semiconductor chip stacked on a surface of the semiconductor chip.
[12] A method for manufacturing a semiconductor device, the method including: laminating the adhesive layer of the dicing/die-bonding integrated film according to [9] onto a semiconductor wafer; producing a plurality of singulated semiconductor chips with an adhesive piece by dicing the semiconductor wafer to which the adhesive layer has been laminated; and bonding a first semiconductor chip with a first adhesive piece, which is one of the plurality of semiconductor chips with an adhesive piece, to a support member via the first adhesive piece.
[13] The method according to [12], further including bonding a second semiconductor chip with a second adhesive piece, which is another of the plurality of semiconductor chips with an adhesive piece, onto a surface of the first semiconductor chip of the first semiconductor chip with the first adhesive piece bonded to the support member, via the second adhesive piece.
[14] A method for manufacturing a semiconductor device, the method including: providing a laminate including: the dicing/die-bonding integrated film according to [9]; and a plurality of semiconductor chips provided on the adhesive layer of the dicing/die-bonding integrated film, the plurality of semiconductor chips being obtained by singulating a semiconductor wafer; producing semiconductor chips with an adhesive piece by irradiating the adhesive layer with a laser through gaps between the plurality of semiconductor chips to singulate the adhesive layer, and bonding a first semiconductor chip with a first adhesive piece, as one of the semiconductor chips with an adhesive piece, to a support member via the first adhesive piece.
[15] The method according to [14], wherein the laminate is a laminate produced by a method including: forming grooves along dicing lines on a circuit formation surface of the semiconductor wafer, producing the plurality of semiconductor chips by grinding a back surface of the semiconductor wafer on which the grooves are formed, the back surface being on an opposite side to the circuit formation surface, to a depth that at least reaches the grooves; and laminating the adhesive layer of the dicing/die-bonding integrated film onto back surfaces of the plurality of semiconductor chips.
[16] The method according to [14] or [15], further including bonding a second semiconductor chip with a second adhesive piece, which is another of the semiconductor chips with an adhesive piece, onto a surface of the first semiconductor chip of the first semiconductor chip with the first adhesive piece bonded to the support member, via the second adhesive piece.
[17] A method for manufacturing a semiconductor device, including bonding a first semiconductor chip and a support member, or the first semiconductor chip and a second semiconductor chip by interposing the film-shaped adhesive according to any one of [1] to [6] between the first semiconductor chip and the support member, or between the first semiconductor chip and the second semiconductor chip.

### Advantageous Effects of Invention

According to the present disclosure, a film-shaped adhesive is provided that exhibits excellent peelability from the pressure-sensitive adhesive layer of a dicing film when applied to the adhesive layer of a dicing/die-bonding integrated film. In addition, according to the present disclosure, a dicing/die-bonding integrated film using such a film-shaped adhesive, and a semiconductor device and a method for manufacturing a semiconductor device are provided. Furthermore, according to the present disclosure, a method for manufacturing a semiconductor device using such a dicing/die-bonding integrated film is provided.

### BRIEF DESCRIPTION OF DRAWINGS

FIG. 1 is a schematic cross-sectional view showing an embodiment of a film-shaped adhesive.

FIG. 2 is a schematic cross-sectional view showing an embodiment of a dicing/die-bonding integrated film.

FIG. 3 is a schematic cross-sectional view showing an embodiment of a semiconductor device.

FIG. 4 is a schematic cross-sectional view showing another embodiment of a semiconductor device.

FIG. 5 is a schematic cross-sectional view showing another embodiment of a semiconductor device.

### DESCRIPTION OF EMBODIMENTS

Hereinafter, embodiments of the present disclosure will be described with appropriate reference to the drawings. However, the present disclosure is not limited to the following embodiments. In the following embodiments, the constituent elements thereof (including steps and the like) are not essential unless otherwise specified. The size of the constituent elements in each drawing is conceptual, and the relative relationship of the sizes between the constituent elements is not limited to that shown in each drawing.

The same applies to the numerical values and their ranges in the present disclosure, and they do not limit the present disclosure. In the present specification, a numerical range indicated using “to” indicates a range including the numerical values described before and after “to” as the minimum value and the maximum value, respectively. In a numerical range described in stages in the present specification, an upper limit value or a lower limit value described in one numerical range may be replaced with an upper limit value or a lower limit value of another numerical range described in stages. Further, in a numerical range described in the present specification, the upper limit value or the lower limit value of the numerical range may be replaced with a value shown in an example. In addition, individually described upper and lower limit values can be arbitrarily combined. Further, “A or B” may include either one of A and B, and may include both. In addition, the materials exemplified below may be used alone as one type or in combination of two or more types, unless otherwise specified. The content of each component in a composition means the total amount of the plurality of substances corresponding to each component present in the composition, unless otherwise specified, when a plurality of such substances exist.

In the present specification, (meth)acrylate means acrylate or a corresponding methacrylate. The same applies to other similar expressions such as (meth)acryloyl group, (meth)acrylic copolymer, and the like.

### [Film-Shaped Adhesive]

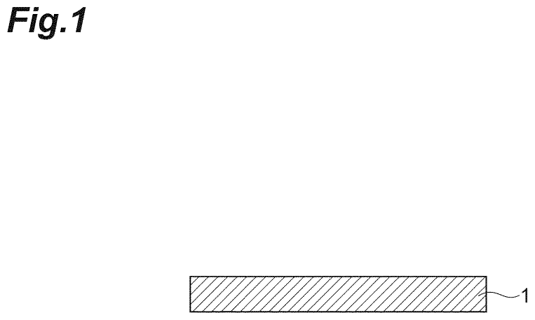

FIG. 1 is a schematic cross-sectional view showing an embodiment of a film-shaped adhesive. The film-shaped adhesive 1 (adhesive film) shown in FIG. 1 may be thermosetting, and may be capable of passing through a semi-cured (B-stage) state to become a fully cured (C-stage) state after a curing treatment.

The B-stage means an intermediate stage in the reaction of certain thermosetting resins in which the material swells when in contact with certain liquids and softens when heated, but does not completely dissolve or melt, and the C-stage means the final stage in the reaction of certain thermosetting resins in which the material becomes practically insoluble and infusible.

According to studies by the inventors of the present disclosure, it was found that when the storage modulus at 25° C. of the film-shaped adhesive 1 in a semi-cured (B-stage) state is 1200 MPa or more, it is possible to reduce the edge peel strength between the pressure-sensitive adhesive layer of the dicing film and the adhesive layer, and the peelability from the pressure-sensitive adhesive layer of the dicing film is improved. The storage modulus at 25° C. may be 1250 MPa or more, 1300 MPa or more, 1350 MPa or more, 1400 MPa or more, 1450 MPa or more, or 1500 MPa or more. The upper limit of the storage modulus at 25° C. may be, for example, 5000 MPa or less or 3000 MPa or less.

In the present specification, the storage modulus at 25° C. of the film-shaped adhesive can be measured, for example, by the following method. A sample for measurement is prepared by laminating a plurality of film-shaped adhesives with a thickness of 10 μm to a thickness of about 160 μm, and cutting this into a size of 4 mm width×33 mm length. The prepared sample is set in a dynamic viscoelasticity measuring device, a tensile load is applied, and the viscoelasticity is measured in a temperature-dependent measurement mode under the conditions of a frequency of 10 Hz, a heating rate of 3° C./min, and a temperature range of −30 to 300° C. Here, the value of the storage modulus at 25° C. is taken as the storage modulus at 25° C.

Next, an embodiment of each component constituting the film-shaped adhesive 1 will be described. By using such components, there is a tendency for the storage modulus at 25° C. of the film-shaped adhesive to be easily adjusted to a predetermined range.

The film-shaped adhesive 1 contains an epoxy resin (hereinafter, may be referred to as “component (A)”), a phenolic resin (hereinafter, may be referred to as “component (B)”), and an elastomer (hereinafter, may be referred to as “component (C)”), and may further contain an inorganic filler (hereinafter, may be referred to as “component (D)”). In addition, the film-shaped adhesive 1 may further contain a coupling agent (hereinafter, may be referred to as “component (E)”), a curing accelerator (hereinafter, may be referred to as “component (F)”), other components, and the like, in addition to component (A), component (B), component (C), and component (D).

### (Component (A): Epoxy Resin)

Component (A) can be used without particular limitation as long as it has an epoxy group in the molecule. Examples of component (A) include bisphenol A type epoxy resins; bisphenol F type epoxy resins; bisphenol S type epoxy resins; phenol novolac type epoxy resins; cresol novolac type epoxy resins; bisphenol A novolac type epoxy resins; bisphenol F novolac type epoxy resins; stilbene type epoxy resins; triazine skeleton-containing epoxy resins; fluorene skeleton-containing epoxy resins; triphenylmethane type epoxy resins; biphenyl type epoxy resins; xylylene type epoxy resins; biphenyl aralkyl type epoxy resins; naphthalene type epoxy resins; and diglycidyl ether compounds of polycyclic aromatics such as polyfunctional phenols and anthracene. Among these, component (A) may include a cresol novolac type epoxy resin, a bisphenol F type epoxy resin, or a bisphenol A type epoxy resin from the viewpoint of film tackiness, flexibility, and the like.

The epoxy equivalent of component (A) is not particularly limited, but may be from 90 to 300 g/eq, from 100 to 290 g/eq, or from 110 to 280 g/eq. When the epoxy equivalent of component (A) is within such a range, there is a tendency for the fluidity of the adhesive composition for forming the film-shaped adhesive to be easily secured while maintaining the bulk strength of the film-shaped adhesive.

Component (A) may include a first epoxy resin having a softening point of 40° C. or less (or an epoxy resin that is liquid at 30° C., hereinafter may be referred to as “component (Aa)”). Component (A) may be a combination of component (Aa) and a second epoxy resin having a softening point of more than 40° C. (or an epoxy resin that is solid at 30° C., hereinafter may be referred to as “component (Ab)”). The softening point of component (Ab) may be, for example, 120° C. or less, 110° C. or less, or 100° C. or less. When component (A) includes component (Aa), there is a tendency for the fracture resistance of the film-shaped adhesive to be more easily improved, and for the storage modulus after curing to be more easily improved. In addition, when component (A) is a combination of component (Aa) and component (Ab), there is a tendency for thinning to be even more easily achieved.

In the present specification, the softening point means a value measured by the ring and ball method in accordance with JIS K7234:1986.

Examples of commercially available products of component (Aa) include EXA-830CRP (trade name, manufactured by DIC Corporation, liquid at 30° C.), YDF-8170C (trade name, manufactured by NIPPON STEEL Chemical & Material Co., Ltd., liquid at 30° C.), EP-4088S (trade name, manufactured by ADEKA CORPORATION, liquid at 30° C.), and the like.

When component (A) is a combination of component (Aa) and component (Ab), the content of component (Aa), from the viewpoint of peelability from the pressure-sensitive adhesive layer, may be 1% by mass or more, 3% by mass or more, 5% by mass or more, 7% by mass or more, or 10% by mass or more, and 50% by mass or less, 45% by mass or less, 40% by mass or less, 35% by mass or less, or 30% by mass or less, based on the total amount of component (A). The content of component (Aa) in component (A) in the adhesive composition for forming the film-shaped adhesive may be the same as the above range.

The content of component (Aa), from the viewpoint of peelability from the pressure-sensitive adhesive layer, may be from 2 to 20% by mass based on the total amount of the film-shaped adhesive. The content of component (Aa) may be 3% by mass or more, 4% by mass or more, or 5% by mass or more, and may be 17% by mass or less, 15% by mass or less, or 12% by mass or less, based on the total amount of the film-shaped adhesive. The content of component (Aa) in the adhesive composition for forming the film-shaped adhesive may be the same as the above range.

In one embodiment, component (Ab) may include a cresol novolac type epoxy resin. In one embodiment, component (Ab) may include a naphthalene type epoxy resin. In one embodiment, component (Ab) may include a cresol novolac type epoxy resin and a naphthalene type epoxy resin. Examples of the naphthalene type epoxy resin include an epoxy resin represented by the following formula (X).

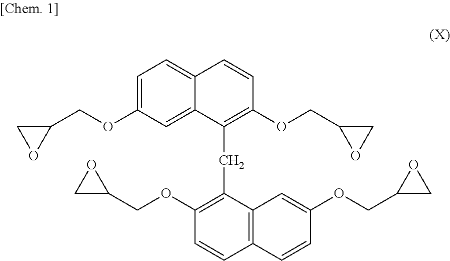 [SMILES: c1cc2ccc(OCC3CO3)c(Cc3c(OCC4CO4)ccc4ccc(OCC5CO5)cc34)c2cc1OCC1CO1]

Examples of commercially available products of the naphthalene type epoxy resin of component (Ab) include HP-4700 (trade name, manufactured by DIC Corporation, softening point: 85 to 95° C.), HP-4770 (trade name, manufactured by DIC Corporation, softening point: 67 to 77° C.), HP-4710 (trade name, manufactured by DIC Corporation, softening point: 85 to 105° C.), and the like.

When component (A) is a combination of component (Aa) and component (Ab), the content of component (Ab) may be 50% by mass or more, 55% by mass or more, 60% by mass or more, 65% by mass or more, or 70% by mass or more, and may be 99% by mass or less, 97% by mass or less, 95% by mass or less, 93% by mass or less, or 90% by mass or less, based on the total amount of component (A). The content of component (Ab) in component (A) in the adhesive composition for forming the film-shaped adhesive may be the same as the above range.

The content of component (A), from the viewpoint of peelability from the pressure-sensitive adhesive layer, may be from 15 to 55% by mass based on the total amount of the film-shaped adhesive. The content of component (A) may be 20% by mass or more, 25% by mass or more, or 30% by mass or more, and may be 50% by mass or less, 45% by mass or less, or 40% by mass or less, based on the total amount of the film-shaped adhesive. The content of component (A) in the adhesive composition for forming the film-shaped adhesive may be the same as the above range.

### (Component (B): Phenolic Resin)

Component (B) can be a component that acts as a curing agent for component (A), that is, a curing agent for the epoxy resin. When the film-shaped adhesive contains component (B), the film-shaped adhesive becomes highly crosslinked, and the storage modulus after curing can be improved.

Component (B) can be used without particular limitation as long as it has a phenolic hydroxyl group in the molecule. Component (B) can be a polycondensation product of phenols such as phenol, cresol, resorcinol, catechol, bisphenol A, bisphenol F, phenylphenol, and aminophenol and/or naphthols such as α-naphthol, β-naphthol, and dihydroxynaphthalene, with aldehydes such as formaldehyde. The polycondensation is usually carried out in the presence of a catalyst such as an acid or a base. A phenolic resin obtained when an acid catalyst is used is particularly called a novolac type phenolic resin. Examples of the novolac type phenolic resin include phenol/formaldehyde novolac resin, cresol/formaldehyde novolac resin, xylenol/formaldehyde novolac resin, resorcinol/formaldehyde novolac resin, phenol-naphthol/formaldehyde novolac resin, and the like. In addition, examples of the phenolic resin also include phenol aralkyl resins, naphthol aralkyl resins, biphenyl aralkyl type phenolic resins, and phenyl aralkyl type phenolic resins synthesized from phenols and/or naphthols such as allylated bisphenol A, allylated bisphenol F, allylated naphthalenediol, phenol novolac, and phenol, and dimethoxyparaxylene or bis(methoxymethyl)biphenyl.

The hydroxyl equivalent of component (B) is not particularly limited, but may be, for example, from 80 to 250 g/eq, from 90 to 200 g/eq, or from 100 to 180 g/eq. When the hydroxyl equivalent of component (B) is 80 g/eq or more, there is a tendency for the storage modulus to be further improved, and when it is 250 g/eq or less, it is possible to prevent problems due to the occurrence of foaming, outgassing, and the like.

The softening point of component (B) is not particularly limited, but may be, for example, from 50 to 140° C., from 55 to 115° C., or from 60 to 100° C.

The ratio of the epoxy equivalent of component (A) to the hydroxyl equivalent of component (B) (epoxy equivalent of component (A)/hydroxyl equivalent of component (B)), from the viewpoint of curability, may be from 0.30/0.70 to 0.70/0.30, from 0.35/0.65 to 0.65/0.35, from 0.40/0.60 to 0.60/0.40, or from 0.45/0.55 to 0.55/0.45. When the equivalent ratio is 0.30/0.70 or more, there is a tendency for more sufficient curability to be obtained. When the equivalent ratio is 0.70/0.30 or less, it is possible to prevent the viscosity from becoming too high, and more sufficient fluidity can be obtained.

The total content of component (A) and component (B) may be from 45 to 80% by mass based on the total amount of the film-shaped adhesive. When the total content of component (A) and component (B) is 40% by mass or more based on the total amount of the film-shaped adhesive, there is a tendency for the storage modulus after curing to be more easily improved, and when it is 80% by mass or less, there is a tendency for better handleability. The total content of component (A) and component (B) may be 50% by mass or more, 55% by mass or more, or 60% by mass or more, and may be 75% by mass or less, 72% by mass or less, or 70% by mass or less, based on the total amount of the film-shaped adhesive. The total content of component (A) and component (B) in the adhesive composition for forming the film-shaped adhesive may be the same as the above range.

### (Component (C): Elastomer)

Examples of component (C) include acrylic resins, polyester resins, polyamide resins, polyimide resins, silicone resins, butadiene resins; modified products of these resins, and the like. Among these, component (C) may be an acrylic resin (acrylic rubber) having, as a main component, a structural unit derived from a (meth)acrylic acid ester, because it has few ionic impurities and excellent heat resistance, makes it easier to ensure the connection reliability of the semiconductor device, and has excellent fluidity. The content of the structural unit derived from a (meth)acrylic acid ester in component (C) may be, for example, 70% by mass or more, 80% by mass or more, or 90% by mass or more, based on the total amount of structural units. The acrylic resin (acrylic rubber) may include a structural unit derived from a (meth)acrylic acid ester having a crosslinkable functional group such as an epoxy group, an alcoholic or phenolic hydroxyl group, or a carboxyl group.

The glass transition temperature (Tg) of component (C) may be from −30 to 30° C. When the Tg of component (C) is −30° C. or more, it is possible to further improve the pressure-sensitive adhesive force of the film-shaped adhesive, and furthermore, there is a tendency to prevent the flexibility of the film-shaped adhesive from becoming too high. When the Tg of component (C) is 30° C. or less, a decrease in the flexibility of the film-shaped adhesive can be suppressed, and there is a tendency for it to be excellent in fracture strength when a thin film is formed and also excellent in processability. The glass transition temperature (Tg) of component (C) may be −20° C. or more or −10° C. or more, and may be 25° C. or less or 20° C. or less. Here, Tg means a value measured using a DSC (Differential Scanning calorimeter) (for example, Thermo Plus 2, manufactured by Rigaku Corporation). The Tg of component (C) can be adjusted to a desired range by adjusting the type and content of the structural units constituting component (C) (in the case where component (C) is an acrylic resin (acrylic rubber), the structural units derived from a (meth)acrylic acid ester).

The weight-average molecular weight (Mw) of component (C) may be 100,000 or more, 300,000 or more, or 500,000 or more, and may be 3,000,000 or less, 2,000,000 or less, or 1,000,000 or less. When the Mw of component (C) is within such a range, film formability, film strength, flexibility, tackiness, and the like can be appropriately controlled, and it is excellent in reflow properties, and embeddability can be improved. Here, Mw means a value measured by gel permeation chromatography (GPC) and converted using a calibration curve based on standard polystyrene. In addition, when a plurality of peaks are observed in GPC, the weight-average molecular weight attributed to the peak with the highest peak intensity is defined as the weight-average molecular weight in the present specification.

Examples of commercially available products of component (C) include SG-70L, SG-708-6, WS-023 EK30, SG-P3, SG-280 EK23, SG-80H, HTR-860P, HTR-860P-3, HTR-860P-3CSP, HTR-860P-3CSP-3 DB, HTR-860P-30B (all manufactured by Nagase ChemteX Corporation), KH-CT-865 (manufactured by Resonac Corporation), and the like.

The content of component (C) is from 20 to 50% by mass based on the total amount of the film-shaped adhesive. When the content of component (C) is 20% by mass or more based on the total amount of the film-shaped adhesive, there is a tendency for it to be excellent in thin film formability and excellent in fracture resistance when a thin film is formed. When the content of component (C) is 50% by mass or less based on the total amount of the film-shaped adhesive, embeddability can be improved by improving fluidity, and there is a tendency for the storage modulus after curing to be more easily improved. The content of component (C) may be 22% by mass or more, 25% by mass or more, or 28% by mass or more, and may be 45% by mass or less, 40% by mass or less, or 38% by mass or less, based on the total amount of the film-shaped adhesive. The content of component (C) in the adhesive composition for forming the film-shaped adhesive may be the same as the above range.

### (Component (D): Inorganic Filler)

The film-shaped adhesive 1 may further contain component (D). That is, there can be an embodiment in which the film-shaped adhesive 1 contains component (D) and an embodiment in which it substantially does not contain component (D).

Examples of component (D) include aluminum hydroxide, magnesium hydroxide, calcium carbonate, magnesium carbonate, calcium silicate, magnesium silicate, calcium oxide, magnesium oxide, aluminum oxide, aluminum nitride, aluminum borate whiskers, boron nitride, silica, and the like. Among these, component (D) may be silica from the viewpoint of adjusting the melt viscosity. The shape of component (D) is not particularly limited, but may be spherical.

The average particle size of component (D), from the viewpoint of fluidity and storage modulus, may be 700 nm or less, and may be 600 nm or less, 500 nm or less, 400 nm or less, 300 nm or less, 200 nm or less, 150 nm or less, or 100 nm or less. The average particle size of component (D) may be, for example, 1 nm or more. Here, the average particle size means the particle size at 50% cumulative frequency in the particle size distribution obtained by a laser diffraction/scattering method. The average particle size of component (D) can also be determined by using the film-shaped adhesive containing component (D). In this case, a dispersion liquid is prepared by dispersing in a solvent the residue obtained by heating the film-shaped adhesive to decompose the resin component, and the average particle size of component (D) can be determined from the particle size distribution obtained by applying a laser diffraction/scattering method to this.

The content of component (D) may be from 0 to 5% by mass based on the total amount of the film-shaped adhesive. When the content of component (D) is within such a range, there is a tendency for thinning to be even more possible. In one embodiment, the content of component (D) may be 3% by mass or less, 2% by mass or less, or 1% by mass or less, based on the total amount of the film-shaped adhesive. In one embodiment, the content of component (D) may be 0% by mass or more, more than 0% by mass, 1% by mass or more, 2% by mass or more, or 3% by mass or more, based on the total amount of the film-shaped adhesive. In one embodiment, the content of component (D) may be 0% by mass based on the total amount of the film-shaped adhesive. The content of component (D) in the adhesive composition for forming the film-shaped adhesive may be the same as the above range.

### (Component (E): Coupling Agent)

Component (E) may be a silane coupling agent. Examples of the silane coupling agent include γ-ureidopropyltriethoxysilane, γ-mercaptopropyltrimethoxysilane, 3-phenylaminopropyltrimethoxysilane, 3-(2-aminoethyl)aminopropyltrimethoxysilane, and the like.

### (Component (F): Curing Accelerator)

Examples of component (F) include imidazoles and their derivatives, organophosphorus compounds, secondary amines, tertiary amines, quaternary ammonium salts, and the like. Among these, from the viewpoint of reactivity, component (F) may be imidazoles and their derivatives.

Examples of imidazoles include 2-methylimidazole, 1-benzyl-2-methylimidazole, 2-phenylimidazole, 1-cyanoethyl-2-phenylimidazole, 1-cyanoethyl-2-methylimidazole, and the like.

### Other Components

The film-shaped adhesive may further contain other components. Examples of other components include pigments, ion scavengers, antioxidants, and the like.

The total content of component (E), component (F), and other components may be 0.1% by mass or more, 0.3% by mass or more, or 0.5% by mass or more, and may be 30% by mass or less, 20% by mass or less, 10% by mass or less, or 5% by mass or less, based on the total mass of the film-shaped adhesive. The total content of component (E), component (F), and other components in the adhesive composition for forming the film-shaped adhesive may be the same as the above range.

The thickness of the film-shaped adhesive 1 may be from 1 to 15 μm. The thickness of the film-shaped adhesive 1 may be 12 μm or less, 10 μm or less, 8 μm or less, or 7 μm or less. The thickness of the film-shaped adhesive 1 can be determined, for example, by measuring the thickness at five locations on a cross-section of the film-shaped adhesive 1 with a scanning electron micrograph and calculating the average of the measured values.

The storage modulus at 150° C. of a cured product obtained by curing the film-shaped adhesive 1 at 150° C. for 30 minutes may be 10 MPa or more, 20 MPa or more, 30 MPa or more, 40 MPa or more, 50 MPa or more, 60 MPa or more, 70 MPa or more, 80 MPa or more, 90 MPa or more, or 100 MPa or more. When the storage modulus is 10 MPa or more, it is possible to cover the brittleness of the semiconductor chip due to thinning, and as a result, it becomes possible to suppress the occurrence of chip cracks. The upper limit of the storage modulus is not particularly limited, but may be, for example, 500 MPa or less, 300 MPa or less, or 250 MPa or less.

In the present specification, the storage modulus at 150° C. of a cured product obtained by curing the film-shaped adhesive at 150° C. for 30 minutes can be measured, for example, by the following method. A sample for measurement is prepared by laminating a plurality of film-shaped adhesives with a thickness of 10 μm to a thickness of about 160 μm, and cutting this into a size of 4 mm width×33 mm length. After curing the prepared sample at 150° C. for 30 minutes, the cured sample is set in a dynamic viscoelasticity measuring device, a tensile load is applied, and the viscoelasticity is measured in a temperature-dependent measurement mode under the conditions of a frequency of 10 Hz, a heating rate of 3° C./min, and a temperature range of −30 to 300° C. Here, the value of the storage modulus at 150° C. is taken as the storage modulus at 150° C.

The minimum melt viscosity of the film-shaped adhesive 1 in the range of 60 to 160° C. may be, for example, 3000 Pa·s or less. When the minimum melt viscosity is 3000 Pa·s or less, the fluidity of the film-shaped adhesive improves, and the embeddability tends to improve. The minimum melt viscosity may be, for example, 2500 Pa·s or less or 2000 Pa·s or less. The lower limit of the minimum melt viscosity may be, for example, 500 Pa·s or more or 700 Pa-s or more.

The shear viscosity (melt viscosity) of the film-shaped adhesive 1 at 100° C. may be, for example, 3500 Pa·s or less from the viewpoint of more excellent embeddability. The shear viscosity (melt viscosity) at 100° C. may be, for example, 3000 Pa·s or less or 2500 Pa·s or less. The lower limit of the shear viscosity (melt viscosity) at 100° C. may be, for example, 500 Pa·s or more or 1000 Pa·s or more.

In the present specification, the minimum melt viscosity in the range of 60 to 160° C. or the shear viscosity (melt viscosity) at 100° C. can be measured as follows. First, a laminate is obtained by laminating the film-shaped adhesive with a laminator so that the thickness becomes 1000 μm (1 mm) or more. A measurement sample having a circular surface with a diameter of 9 mm is punched out from the obtained laminate, and for the obtained measurement sample, measurement is performed using a viscoelasticity measuring device under the conditions of a measurement temperature of 60 to 160° C., a heating rate of 5° C./min, a strain of 5%, a measurement frequency of 4 Hz, and an initial load of 10 g, and the minimum melt viscosity, which is the lowest value within the measurement temperature range, and the melt viscosity at 100° C. are derived.

The film-shaped adhesive 1 (adhesive film) shown in FIG. 1 is formed by molding an adhesive composition containing component (A), component (B), component (C), component (D), component (E), component (F), other components, and the like into a film shape. Such a film-shaped adhesive 1 can be formed by applying the adhesive composition to a support film. In the formation of the film-shaped adhesive 1, a varnish (adhesive varnish) containing the adhesive composition and a solvent may be used. When using an adhesive varnish, the film-shaped adhesive 1 can be obtained by preparing the adhesive varnish by mixing or kneading the contained components in a solvent, applying the obtained adhesive varnish to a support film, and removing the solvent by heating and drying.

The support film is not particularly limited as long as it can withstand the above-mentioned heating and drying, but may be, for example, a polyester film, a polypropylene film, a polyethylene terephthalate film, a polyimide film, a polyetherimide film, a polyethylene naphthalate film, a polymethylpentene film, or the like. The support film may be a multilayer film combining two or more types, and its surface may be treated with a release agent such as a silicone-based or silica-based agent. The thickness of the support film may be, for example, from 10 to 200 μm or from 20 to 170 μm.

Mixing or kneading can be performed using a normal stirrer, a triturator, a three-roll mill, a ball mill, or other dispersing machines, by appropriately combining them.

The solvent used for preparing the adhesive varnish is not limited as long as it can uniformly dissolve, knead, or disperse each component, and conventionally known ones can be used. Examples of such a solvent include ketone-based solvents such as acetone, methyl ethyl ketone, methyl isobutyl ketone, and cyclohexanone, dimethylformamide, dimethylacetamide, N-methylpyrrolidone, toluene, xylene, and the like. The solvent may be methyl ethyl ketone or cyclohexanone from the viewpoint of drying speed and cost.

As a method for applying the adhesive varnish to the support film, a known method can be used, for example, a knife coating method, a roll coating method, a spray coating method, a gravure coating method, a bar coating method, a curtain coating method, or the like can be used. The heating and drying conditions are not particularly limited as long as the used solvent sufficiently volatilizes, but may be from 50 to 150° C. for 1 to 30 minutes.

Since the film-shaped adhesive 1 can be made into a thin film, it can be suitably used in a manufacturing process for a semiconductor device formed by stacking a plurality of semiconductor chips. In this case, the semiconductor device may be a stacked MCP, and may be a 3D NAND memory.

### [Dicing/Die-Bonding Integrated Film]

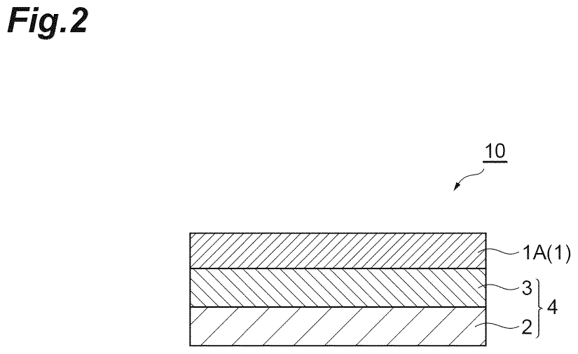

FIG. 2 is a schematic cross-sectional view showing an embodiment of a dicing/die-bonding integrated film. The dicing/die-bonding integrated film 10 shown in FIG. 2 includes, in this order, a base layer 2, a pressure-sensitive adhesive layer 3, and an adhesive layer 1A consisting of the above-mentioned film-shaped adhesive 1. The laminate composed of the base layer 2 and the pressure-sensitive adhesive layer 3 can be a dicing film 4. When such a dicing/die-bonding integrated film 10 is used, the lamination step onto a semiconductor wafer is performed only once, which makes it possible to improve the efficiency of the work. The dicing/die-bonding integrated film may be in the form of a film, a sheet, a tape, or the like.

The dicing film 4 includes a base layer 2 and a pressure-sensitive adhesive layer 3 provided on the base layer 2.

Examples of the base layer 2 include plastic films such as a polytetrafluoroethylene film, a polyethylene terephthalate film, a polyethylene film, a polypropylene film, a polymethylpentene film, a polyimide film, and an ethylene vinyl acetate film. These base layers 2 may be multilayer films combining two or more types. These base layers 2 may be subjected to surface treatment such as primer application, UV treatment, corona discharge treatment, polishing treatment, or etching treatment, as necessary.

The pressure-sensitive adhesive layer 3 is a layer made of a pressure-sensitive adhesive. The pressure-sensitive adhesive is not particularly limited as long as it has sufficient pressure-sensitive adhesive force to prevent semiconductor chips from scattering during the dicing step, and has a low enough pressure-sensitive adhesive force not to damage the semiconductor chips in the subsequent semiconductor chip pickup step, and conventionally known ones in the field of dicing films can be used. The pressure-sensitive adhesive may be either a radiation-curable type or a non-radiation-curable type. A non-radiation-curable pressure-sensitive adhesive is a pressure-sensitive adhesive that exhibits a certain adhesiveness with a short period of pressurization. On the other hand, a radiation-curable pressure-sensitive adhesive is a pressure-sensitive adhesive that has the property of decreasing in adhesiveness upon irradiation with radiation (for example, ultraviolet rays).

The thickness of the dicing film 4 (base layer 2 and pressure-sensitive adhesive layer 3) may be from 60 to 150 μm or from 70 to 130 μm from the viewpoint of economy and film handleability.

The dicing/die-bonding integrated film 10 can be obtained, for example, by providing the film-shaped adhesive 1 and the dicing film 4, and laminating the film-shaped adhesive 1 and the pressure-sensitive adhesive layer 3 of the dicing film 4 together. In addition, the dicing/die-bonding integrated film 10 can also be obtained, for example, by providing the dicing film 4 and applying the adhesive composition (adhesive varnish) onto the pressure-sensitive adhesive layer 3 of the dicing film 4 in the same manner as the method for forming the above-mentioned film-shaped adhesive 1.

When laminating the film-shaped adhesive 1 and the pressure-sensitive adhesive layer 3 of the dicing film 4, the dicing/die-bonding integrated film 10 can be formed by laminating the film-shaped adhesive 1 onto the dicing film 4 under predetermined conditions (for example, room temperature (20° C.) or a heated state) using a roll laminator, a vacuum laminator, or the like. The dicing/die-bonding integrated film 10 may be formed using a roll laminator in a heated state because it can be manufactured continuously and is excellent in efficiency.

The film-shaped adhesive and the dicing/die-bonding integrated film may be used in a manufacturing process for a semiconductor device, and may be used in a manufacturing process for a semiconductor device formed by stacking a plurality of semiconductor chips. The film-shaped adhesive and the dicing/die-bonding integrated film may be used in a manufacturing process for a semiconductor device including obtaining a semiconductor chip with an adhesive piece by laminating the film-shaped adhesive or the adhesive layer of the dicing/die-bonding integrated film onto a semiconductor wafer or an already singulated semiconductor chip and dividing it by a rotating blade, a laser, or stretching, and bonding the semiconductor chip with an adhesive piece onto a support member or another semiconductor chip via the adhesive piece.

The film-shaped adhesive is also suitably used as an adhesive for bonding semiconductor chips to each other in a stacked MCP (for example, a 3D NAND memory), which is a semiconductor device formed by stacking a plurality of semiconductor chips.

The film-shaped adhesive can also be used, for example, as a protective sheet for protecting the back surface of a semiconductor chip in a flip-chip type semiconductor device, a sealing sheet for sealing between the surface of a semiconductor chip in a flip-chip type semiconductor device and an adherend, and the like.

A semiconductor device manufactured using the film-shaped adhesive and the dicing/die-bonding integrated film will be specifically described below with reference to the drawings. In recent years, semiconductor devices with various structures have been proposed, and the use of the film-shaped adhesive and the dicing/die-bonding integrated film of the present embodiment is not limited to semiconductor devices with the structures described below.

### [Semiconductor Device]

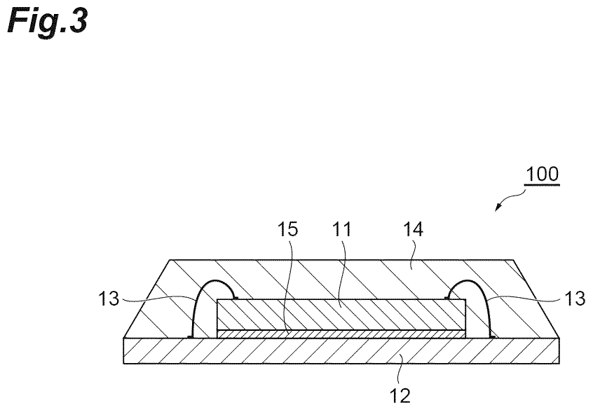

FIG. 3 is a schematic cross-sectional view showing an embodiment of a semiconductor device. The semiconductor device 100 shown in FIG. 3 includes a semiconductor chip 11 (first semiconductor chip), a support member 12 on which the semiconductor chip 11 is mounted, and an adhesive member 15. The adhesive member 15 is provided between the semiconductor chip 11 and the support member 12, and bonds the semiconductor chip 11 and the support member 12. The adhesive member 15 is a cured product of the adhesive composition (cured product of the film-shaped adhesive). Connection terminals (not shown) of the semiconductor chip 11 are electrically connected to external connection terminals (not shown) via bonding wires 13, and are sealed with an encapsulant 14.

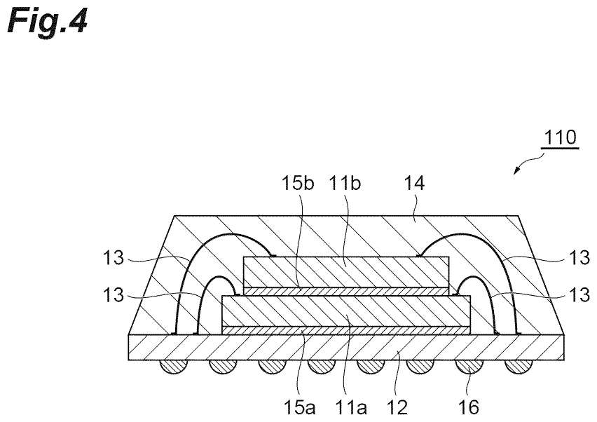

FIG. 4 is a schematic cross-sectional view showing another embodiment of a semiconductor device. In the semiconductor device 110 shown in FIG. 4, a first-stage semiconductor chip 11a (first semiconductor chip) is bonded to a support member 12 on which terminals 16 are formed, by an adhesive member 15a (a cured product of the adhesive composition (a cured product of the film-shaped adhesive)), and a second-stage semiconductor chip 11b (second semiconductor chip) is further bonded onto the first-stage semiconductor chip 11a by an adhesive member 15b (a cured product of the adhesive composition (a cured product of the film-shaped adhesive)). Connection terminals (not shown) of the first-stage semiconductor chip 11a and the second-stage semiconductor chip 11b are electrically connected to external connection terminals via bonding wires 13 and are sealed with an encapsulant 14. It can also be said that the semiconductor device 110 shown in FIG. 4 further includes a different semiconductor chip (11b) stacked on the surface of the semiconductor chip (11a) in the semiconductor device 100 shown in FIG. 3.

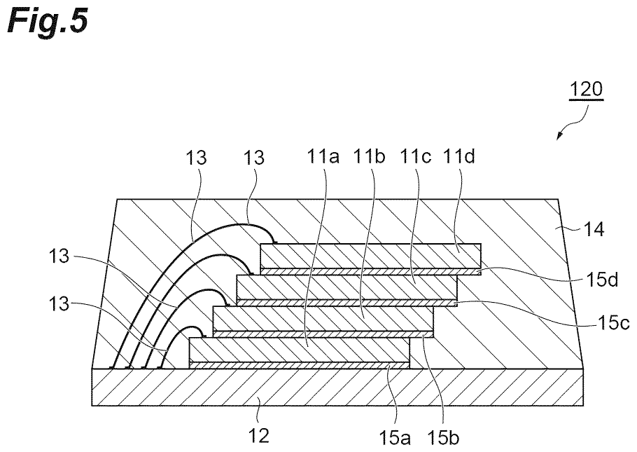

FIG. 5 is a schematic cross-sectional view showing another embodiment of a semiconductor device. The semiconductor device 120 shown in FIG. 5 includes a support member 12, and a semiconductor chip 11a (first semiconductor chip), 11b (second semiconductor chip), 11c (third semiconductor chip), and 11d (fourth semiconductor chip) stacked on the support member 12. The four semiconductor chips 11a, 11b, 11c, and 11d are stacked at positions shifted from each other in the lateral direction (a direction orthogonal to the stacking direction) for connection with connection terminals (not shown) formed on the surface of the support member 12 (see FIG. 5). The semiconductor chip 11a is bonded to the support member 12 by an adhesive member 15a (a cured product of the adhesive composition (a cured product of the film-shaped adhesive)), and adhesive members 15b, 15c, and 15d (cured products of the adhesive composition (cured products of the film-shaped adhesive)) are also interposed between the three semiconductor chips 11b, 11c, and 11d, respectively. It can also be said that the semiconductor device 120 shown in FIG. 5 further includes different semiconductor chips (11b, 11c, 11d) stacked on the surface of the semiconductor chip (11a) in the semiconductor device 100 shown in FIG. 3.

Although the semiconductor device (semiconductor package) as an embodiment of the present disclosure has been described in detail above, the present disclosure is not limited to the above-described embodiments. For example, in FIG. 5, a semiconductor device in a mode where four semiconductor chips are stacked is illustrated, but the number of stacked semiconductor chips is not limited to this. Further, in FIG. 5, a semiconductor device in a mode where the semiconductor chips are stacked at positions shifted from each other in the lateral direction (a direction orthogonal to the stacking direction) is illustrated, but it may be a semiconductor device in a mode where the semiconductor chips are stacked at positions not shifted from each other in the lateral direction (a direction orthogonal to the stacking direction).

### [Method for Manufacturing a Semiconductor Device]

The semiconductor devices (semiconductor packages) shown in FIG. 3, FIG. 4, and FIG. 5 can be obtained by a method including bonding a semiconductor chip (first semiconductor chip) and a support member, or a semiconductor chip (first semiconductor chip) and a semiconductor chip (second semiconductor chip), by interposing the above-mentioned film adhesive between the semiconductor chip (first semiconductor chip) and the support member, or between the semiconductor chip (first semiconductor chip) and the semiconductor chip (second semiconductor chip). More specifically, they can be obtained by interposing the above-mentioned film-shaped adhesive between a semiconductor chip and a support member, or between a semiconductor chip (first semiconductor chip) and a semiconductor chip (second semiconductor chip), bonding them together by thermocompression bonding, and then, as necessary, undergoing a thermal curing step, a wire bonding step, a sealing step with an encapsulant, a heat-melting step including reflow with solder, and the like.

As a method for interposing the film-shaped adhesive between the semiconductor chip (first semiconductor chip) and the support member, or between the semiconductor chip (first semiconductor chip) and the semiconductor chip (second semiconductor chip), it may be a method of first producing a semiconductor chip with an adhesive piece, as described later, and then laminating it onto a support member or another semiconductor chip.

Next, an embodiment of a method for manufacturing a semiconductor device using the dicing/die-bonding integrated film shown in FIG. 2 will be described. The method for manufacturing a semiconductor device using the dicing/die-bonding integrated film is not limited to the method for manufacturing a semiconductor device described below.

One embodiment of a method for manufacturing a semiconductor device includes, for example, laminating a semiconductor wafer onto the adhesive layer of the above-mentioned dicing/die-bonding integrated film, producing a plurality of singulated semiconductor chips with an adhesive piece by dicing the semiconductor wafer to which the adhesive layer has been laminated, and bonding a first semiconductor chip with a first adhesive piece, which is one of the semiconductor chips with an adhesive piece, to a support member via the first adhesive piece (bonding a semiconductor chip with an adhesive piece to a support member via the adhesive piece) (first bonding step). Another embodiment of a method for manufacturing a semiconductor device includes, for example, providing a laminate including the above-mentioned dicing/die-bonding integrated film and a plurality of semiconductor chips provided on the adhesive layer of the dicing/die-bonding integrated film, the plurality of semiconductor chips being obtained by singulating a semiconductor wafer (laminate providing step), producing semiconductor chips with an adhesive piece by irradiating the adhesive layer with a laser through gaps between the plurality of semiconductor chips to singulate the adhesive layer, and bonding a first semiconductor chip with a first adhesive piece, as one of the semiconductor chips with an adhesive piece, to a support member via the first adhesive piece (bonding a semiconductor chip with an adhesive piece to a support member via the adhesive piece) (first bonding step).

The method for manufacturing a semiconductor device may further include bonding a second semiconductor chip with a second adhesive piece, which is another of the semiconductor chips with an adhesive piece, onto a surface of the first semiconductor chip of the first semiconductor chip with the first adhesive piece bonded to the support member, via the second adhesive piece (bonding another semiconductor chip with an adhesive piece onto a surface of the semiconductor chip bonded to the support member, via the adhesive piece that the other semiconductor chip with an adhesive piece has) (second bonding step).

The lamination step is pressure-bonding a semiconductor wafer to the adhesive layer 1A of the dicing/die-bonding integrated film 10 and laminating it by adhesive retention. This step may be performed while pressing with a pressing means such as a pressure-bonding roll.

Examples of the semiconductor wafer include single-crystal silicon, polycrystalline silicon, various ceramics, compound semiconductors such as gallium arsenide, and the like.

The dicing step is dicing the semiconductor wafer. This makes it possible to cut the semiconductor wafer to a predetermined size and manufacture a plurality of singulated semiconductor chips with an adhesive piece. Dicing can be performed, for example, from the circuit surface side of the semiconductor wafer according to a conventional method. In this step, for example, a method called full-cut, in which a cut is made down to the dicing film, a method in which the semiconductor wafer is half-cut and then divided by cooling and pulling, a method of dividing by laser, and the like can be adopted. The dicing apparatus used in this step is not particularly limited, and a conventionally known one can be used.

The semiconductor chip is composed of, for example, a circuit layer and a semiconductor layer (for example, single-crystal silicon, polycrystalline silicon, various ceramics, a compound semiconductor such as gallium arsenide). Examples of the semiconductor chip include ICs (integrated circuits) and the like. Examples of the support member include lead frames such as a 42-alloy lead frame and a copper lead frame; plastic films such as a polyimide resin and an epoxy resin; modified plastic films in which a base material such as glass nonwoven fabric is impregnated with a plastic such as a polyimide resin or an epoxy resin and cured; ceramics such as alumina, and the like.

The laminate providing step is providing a laminate including a dicing/die-bonding integrated film and a plurality of semiconductor chips provided on the adhesive layer of the dicing/die-bonding integrated film, the plurality of semiconductor chips being obtained by singulating a semiconductor wafer. In this step, the method is not particularly limited as long as a laminate having a predetermined configuration can be obtained. The laminate may be a laminate produced by a method including forming grooves along dicing lines on a circuit formation surface of the semiconductor wafer (step (a)), producing a plurality of semiconductor chips by grinding a back surface of the semiconductor wafer on which the grooves are formed, the back surface being on an opposite side to the circuit formation surface, to a depth that at least reaches the grooves (step (b)), and laminating the adhesive layer of the dicing/die-bonding integrated film onto back surfaces of the plurality of semiconductor chips (step (c)).

In step (a), grooves are formed along dicing lines on a circuit formation surface of a semiconductor wafer. As the semiconductor wafer, for example, the same ones as described above can be exemplified. The semiconductor wafer usually has a circuit formation surface and a back surface on an opposite side to the circuit formation surface.

The thickness of the semiconductor wafer is greater than the thickness of the semiconductor chip. The thickness of the semiconductor wafer may be, for example, from 50 to 3000 μm, from 100 to 2000 μm, or from 200 to 1500 μm.

The grooves are formed by performing half-cut dicing using a dicing blade along the dicing lines of the semiconductor wafer. Half-cut dicing means cutting to a predetermined depth so as not to completely cut the semiconductor wafer. Half-cut dicing with a dicing blade can be performed using a commercially available dicing saw. The grooves are formed on the circuit formation surface of the semiconductor wafer, for example, so as to form a grid pattern in a plan view.

In step (b), a plurality of semiconductor chips are produced by grinding a back surface of the semiconductor wafer on which the grooves are formed, the back surface being on an opposite side to the circuit formation surface, to a depth that at least reaches the grooves.

In step (b), first, a backgrind tape is laminated onto the circuit formation surface of the semiconductor wafer on which the grooves are formed. As the backgrind tape, a backgrind tape used in this field can be used, and for example, it may be a backgrind tape including a pressure-sensitive adhesive layer including an ultraviolet-curable pressure-sensitive adhesive.

Subsequently, the back surface of the semiconductor wafer on which the grooves are formed is ground. Grinding the back surface of the semiconductor wafer on which the grooves are formed can be performed using a general grinder. By grinding the back surface in this way, a plurality of semiconductor chips having a thickness smaller than the thickness of the semiconductor wafer can be produced. The semiconductor chip usually has a circuit formation surface and a back surface on an opposite side to the circuit formation surface. The thickness of the semiconductor chip is smaller than the thickness of the semiconductor wafer. The thickness of the semiconductor chip may be, for example, from 10 to 200 μm, and may be from 20 to 100 μm. The thicknesses of all the semiconductor chips may be the same or different from each other.

In step (c), the adhesive layer of the above-mentioned dicing/die-bonding integrated film is laminated onto the back surfaces of the plurality of semiconductor chips obtained above. In this way, a laminate A having a base layer, a pressure-sensitive adhesive layer, an adhesive layer, a plurality of semiconductor chips, and a backgrind tape in this order can be obtained.

Subsequently, a laminate can be obtained by peeling the backgrind tape from the laminate A. When the backgrind tape includes a pressure-sensitive adhesive layer including an ultraviolet-curable pressure-sensitive adhesive, the backgrind tape can be efficiently peeled from the laminate A by irradiating the pressure-sensitive adhesive layer of the backgrind tape with ultraviolet rays to cure the pressure-sensitive adhesive layer and reduce its pressure-sensitive adhesive force.

The adhesive layer singulation step produces a semiconductor chip with an adhesive piece, which has a semiconductor chip and an adhesive piece, by irradiating the adhesive layer with a laser through the gaps between the plurality of semiconductor chips to singulate the adhesive layer.

The plurality of semiconductor chips obtained by singulating a semiconductor wafer usually have gaps between the plurality of semiconductor chips. By irradiating the adhesive layer with a laser through the gaps, adhesive layer pieces having a shape similar to the planar view shape of the semiconductor chips can be obtained.

The laser irradiation is performed, for example, from the semiconductor chip side through the gaps between the plurality of semiconductor chips. The laser irradiation can be performed using a commercially available laser saw. The frequency of the laser may be, for example, from 30 to 250 kHz, from 50 to 200 kHz, or from 80 to 120 KHz. The output of the laser may be, for example, from 0.05 to 2.0 W, from 0.1 to 1.0 W, or from 0.2 to 0.5 W. The feed rate in the laser irradiation may be, for example, from 20 to 500 mm/s, from 50 to 400 mm/s, or from 100 to 300 mm/s.

The method for manufacturing a semiconductor device may include a pickup step, as necessary. The pickup step is picking up a semiconductor chip with an adhesive piece in order to peel the semiconductor chip with an adhesive piece that is adhesively fixed to a dicing/die-bonding integrated film or a dicing film. The pickup method is not particularly limited, and various conventionally known methods can be adopted. Examples of such a method include a method of pushing up individual semiconductor chips with an adhesive piece from the dicing/die-bonding integrated film or dicing film side with a needle, and picking up the pushed-up semiconductor chip with an adhesive piece with a pickup device.

Here, the pickup can be performed after irradiating the pressure-sensitive adhesive layer with radiation when the pressure-sensitive adhesive layer is of a radiation (e.g., ultraviolet) curable type. This reduces the pressure-sensitive adhesive force of the pressure-sensitive adhesive layer to the adhesive piece, making it easier to peel off the semiconductor chip with an adhesive piece. As a result, pickup is possible without damaging the semiconductor chip with an adhesive piece.

The first bonding step is bonding the first semiconductor chip with a first adhesive piece, formed by dicing, to a support member for mounting a semiconductor chip, via the first adhesive piece. The method for manufacturing a semiconductor device may, as necessary, include bonding a second semiconductor chip with a second adhesive piece to the surface of the semiconductor chip bonded to the support member, via the second adhesive piece (second bonding step). Both bondings can be performed by thermocompression. The thermocompression conditions are not particularly limited and can be set as appropriate as necessary. The thermocompression conditions may be, for example, a temperature of 80 to 160° C., a load of 5 to 15 N, and a time of 1 to 10 seconds. As the support member, the same support members as described above can be exemplified.

The method for manufacturing a semiconductor device may, as necessary, include further thermally curing the adhesive piece (the first adhesive piece in the first semiconductor chip with a first adhesive piece, and the second adhesive piece in the second semiconductor chip with a second adhesive piece) or the film-shaped adhesive (thermal curing step). By further thermally curing the adhesive piece (the first adhesive piece in the first semiconductor chip with a first adhesive piece, and the second adhesive piece in the second semiconductor chip with a second adhesive piece) that bonds the semiconductor chip (first semiconductor chip) and the support member, as well as the semiconductor chip (first semiconductor chip) and the semiconductor chip (second semiconductor chip), more robust adhesive fixing becomes possible. When performing thermal curing, pressure may be applied simultaneously during curing. The heating temperature in this step can be appropriately changed depending on the constituent components of the adhesive piece. The heating temperature may be, for example, from 60 to 200° C. or from 100 to 180° C. The temperature or pressure may be changed in stages. The heating time may be, for example, from 1 to 120 minutes or from 15 to 60 minutes.

The method for manufacturing a semiconductor device may, as necessary, include electrically connecting the first semiconductor chip and the second semiconductor chip to the support member with bonding wires, more specifically, electrically connecting electrode pads on the semiconductor chip and the tips of the terminal portions (inner leads) of the support member with bonding wires (wire bonding step). As the bonding wires, for example, gold wires, aluminum wires, copper wires, or the like are used. The temperature during wire bonding may be in the range of 80 to 250° C. or 80 to 220° C. The heating time may be from several seconds to several minutes. Wire bonding may be performed by the combined use of vibrational energy from ultrasonic waves and compression energy from applied pressure while being heated within the above temperature range.

The method for manufacturing a semiconductor device may, as necessary, include encapsulating the semiconductor chip with an encapsulant (encapsulating step). This step is performed to protect the semiconductor chip or bonding wires mounted on the support member. This step can be performed by molding a resin for encapsulation (encapsulating resin) with a mold. The encapsulating resin may be, for example, an epoxy-based resin. The support member and residue are embedded by the heat and pressure during encapsulation, and peeling due to bubbles at the adhesive interface can be prevented.

The method for manufacturing a semiconductor device may, as necessary, include completely curing the insufficiently cured encapsulating resin in the encapsulating step (post-curing step). In the encapsulating step, even if the adhesive piece is not thermally cured, in this step, the adhesive piece can be thermally cured and adhesively fixed along with the curing of the encapsulating resin. The heating temperature in this step can be appropriately set depending on the type of encapsulating resin, and may be, for example, in the range of 165 to 185° C., and the heating time may be about 0.5 to 8 hours.

The method for manufacturing a semiconductor device may, as necessary, include heating the semiconductor chip with an adhesive piece bonded to the support member using a reflow furnace (heating/melting step). In this step, the resin-encapsulated semiconductor device may be surface-mounted on the support member. As a method for surface mounting, for example, reflow soldering, in which solder is supplied onto a printed wiring board in advance and then heated and melted by hot air or the like to perform soldering, can be mentioned. Examples of the heating method include hot air reflow, infrared reflow, and the like. The heating method may be one that heats the whole or one that heats locally. The heating temperature may be, for example, in the range of 240 to 280° C.

### EXAMPLES

Hereinafter, the present disclosure will be specifically described based on examples, but the present disclosure is not limited to these.

### [Production of Film-Shaped Adhesive]

### Examples 1 to 7 and Comparative Example 1

### <Preparation of Adhesive Varnish>

Cyclohexanone was added to a mixture consisting of component (A), component (B), component (D), and component (E) with the components and contents (unit: parts by mass) shown in Table 1, and the mixture was stirred and mixed. To this, component (C) was added with the component and content (unit: parts by mass) shown in Table 1 and stirred, and component (F) was further added and stirred until each component became uniform, to prepare adhesive varnishes of Examples 1 to 6 and Comparative Examples 1 and 2. Note that each component shown in Table 1 means the following, and the numerical values shown in Table 1 mean parts by mass of the components excluding solvents and the like.

### Component (A): Epoxy Resin

### Component (A): Epoxy Resin

### Component (Aa): First Epoxy Resin

(Aa-1) EXA-830CRP (trade name, manufactured by DIC Corporation, bisphenol F type epoxy resin, epoxy equivalent: 160 g/eq, liquid at 30° C.)

### Component (Ab): Second Epoxy Resin

(Ab-1) HP-4710 (trade name, manufactured by DIC Corporation, epoxy resin represented by the above formula (X), epoxy equivalent: 170 g/eq, softening point: 85 to 105° C.)
(Ab-2) N-500P-10 (trade name, manufactured by DIC Corporation, o-cresol novolac type epoxy resin, epoxy equivalent: 204 g/eq, softening point: 75 to 85° C.)

### Component (B): Phenolic Resin

(B-1) MEH-7800M (trade name, manufactured by Meiwa Chemical Co., Ltd., phenol novolac type phenolic resin, hydroxyl equivalent: 175 g/eq, softening point: 61 to 90° C.)

### Component (C): Elastomer

(C-1) HTR-860P-3CSP (trade name, manufactured by Nagase ChemteX Corporation, acrylic rubber, glass transition temperature: −7° C., weight-average molecular weight: 800,000)

### Component (D): Inorganic Filler

(D-1) R972 (trade name, manufactured by Nippon Aerosil Co., Ltd., silica, average particle size 0.016 μm (16 nm))

### Component (E): Coupling Agent

(E-1) A-189 (trade name, manufactured by Nippon Unicar Company Limited, γ-mercaptopropyltrimethoxysilane)

### Component (F): Curing Accelerator

(F-1) 2PZ-CN (trade name, manufactured by Shikoku Chemicals Corporation, 1-cyanoethyl-2-phenylimidazole)

### <Production of Film-Shaped Adhesive>

The adhesive varnishes of Examples 1 to 7 and Comparative Example 1 were filtered through a 500-mesh filter and vacuum-defoamed. A release-treated polyethylene terephthalate (PET) film with a thickness of 38 μm was prepared as a support film, and the adhesive varnish after vacuum defoaming was applied onto the PET film. The applied adhesive varnish was heated and dried at 90° C. for 5 minutes, and then at 130° C. for 5 minutes to obtain the film-shaped adhesives of Examples 1 to 7 and Comparative Example 1 in a B-stage state with a thickness of 10 μm. The thickness of the film-shaped adhesive was adjusted by the coating amount of the adhesive varnish.

### [Evaluation of Film-Shaped Adhesive]

### <Measurement of Storage Modulus at 25° C.>

Using the film-shaped adhesives of Examples 1 to 7 and Comparative Example 1, the storage modulus at 25° C. was measured. The storage modulus at 25° C. was measured by the following method. That is, a sample for measurement was prepared by laminating a plurality of film-shaped adhesives with a thickness of 10 μm to a thickness of about 160 μm, and cutting this into a size of 4 mm width×33 mm length. The prepared sample was set in a dynamic viscoelasticity measuring device (Rheogel E-4000, manufactured by UBM Co., Ltd.), a tensile load was applied, and the viscoelasticity was measured in a temperature-dependent measurement mode under the conditions of a frequency of 10 Hz, a heating rate of 3° C./min, and a temperature range of −30 to 300° C., to determine the value of the storage modulus at 25° C. The results are shown in Table 1.

### <Measurement of Shear Viscosity (Melt Viscosity)>

Multiple sheets of each of the film-shaped adhesives of Examples 1 to 7 and Comparative Example 1 were laminated at 70° C. to form a laminate having a thickness of 1000 μm (1 mm) or more. A measurement sample having a circular surface with a diameter of 9 mm was punched out from the laminate, and the measurement sample was mounted on a circular aluminum plate jig with a diameter of 8 mm. Using an ARES (manufactured by TA Instruments Japan Inc.), the shear viscosity of the measurement sample was measured under the following conditions. From the measurement results, the minimum value of shear viscosity (minimum melt viscosity) in the range of 60 to 160° C. and the shear viscosity at 100° C. were derived. For the minimum melt viscosity and the shear viscosity at 100° C., a smaller value (e.g., 3000 Pa·s or less (minimum melt viscosity), and 3500 Pa·s or less (shear viscosity at 100° C.)) means higher fluidity and excellent embeddability. The results are shown in Table 1.

### (Measurement Conditions)

Measurement temperature: 60 to 160° C.
Heating rate: 5° C./min
Strain: 5%.
Frequency: 4 Hz
Initial load: 10 g
   <Measurement of High-Temperature Storage Modulus after Curing>

Using the film-shaped adhesives of Examples 1 to 7 and Comparative Example 1, the high-temperature storage modulus after curing was measured. The high-temperature storage modulus after curing was measured by the following method. That is, a sample for measurement was prepared by laminating a plurality of film-shaped adhesives with a thickness of 10 μm to a thickness of about 160 μm, and cutting this into a size of 4 mm width×33 mm length. After curing the prepared sample under the conditions of 150° C. for 30 minutes, the cured sample was set in a dynamic viscoelasticity measuring device (Rheogel E-4000, manufactured by UBM Co., Ltd.), a tensile load was applied, and the viscoelasticity was measured in a temperature-dependent measurement mode under the conditions of a frequency of 10 Hz, a heating rate of 3° C./min, and a temperature range of −30 to 300° C., and the value of the storage modulus at 150° C. was taken as the high-temperature storage modulus. For the high-temperature storage modulus, a larger value (e.g., 10 MPa or more) means that the occurrence of chip cracks can be suppressed. The results are shown in Table 1.

### <Measurement of Edge Peel Strength>

Using the film-shaped adhesives of Examples 1 to 7 and Comparative Example 1, the edge peel strength was measured. The edge peel strength was measured by the following method. First, a dicing film was provided, including a base layer (polypropylene/ethylene vinyl acetate/polypropylene (PP/EVA/PP) film, thickness: 100 μm) and a pressure-sensitive adhesive layer (thickness: 10 μm) made of an ultraviolet curable pressure-sensitive adhesive provided on the base layer. Next, by laminating the film-shaped adhesive and the pressure-sensitive adhesive layer of the dicing film, the dicing/die-bonding integrated films of Examples 1 to 7 and Comparative Example 1 were produced, including a base layer, a pressure-sensitive adhesive layer, and an adhesive layer in this order.

A semiconductor wafer with a thickness of 775 μm was provided, and a half-cut was performed on the circuit formation surface (surface) of the semiconductor wafer using a full-auto dicer (DFD6361, manufactured by DISCO Corporation) to form grooves with a depth of 60 μm. The dicing blade used was ZH05-SD4000-N1-70-DD manufactured by DISCO Corporation, and the rotation speed and cut speed were 40,000 rpm and 30 mm/s, respectively. The size of the semiconductor chip was 4 mm×12 mm.

Next, using a backgrind tape laminator (RAD-3520F/12, manufactured by Lintec Corporation), a backgrind tape was laminated onto the circuit formation surface (surface) of the semiconductor wafer, and then, using a grinder (DGP8761, manufactured by DISCO Corporation), the semiconductor wafer was ground from the back surface side so that the thickness of the finally obtained semiconductor chip would be 25 μm, and the semiconductor wafer was singulated into a plurality of semiconductor chips.

Subsequently, in order to reduce the pressure-sensitive adhesive force between the backgrind tape and the semiconductor chip, the backgrind tape was irradiated with ultraviolet rays using a wafer mounter (DFM2800, manufactured by DISCO Corporation). Thereafter, using the same wafer mounter (DFM2800, manufactured by DISCO Corporation), each dicing/die-bonding integrated film was laminated onto the back surface of the singulated semiconductor wafer (back surface of the semiconductor chip) under the conditions of a temperature of 70° C., a tension level of 5, and a lamination speed of 10 mm/sec. At this time, a ring frame was attached to the outer peripheral region of the dicing tape. Thereafter, by peeling off the backgrind tape, a laminate (1) was obtained, including the dicing/die-bonding integrated film and a plurality of semiconductor chips provided on the adhesive layer of the dicing/die-bonding integrated film, the plurality of semiconductor chips being obtained by singulating a semiconductor wafer.

Subsequently, in the laminate (1), using a laser saw (DFL7160, manufactured by DISCO Corporation), a laser was irradiated through the gaps between the semiconductor chips to cut the adhesive layer. The laser irradiation conditions were a frequency of 100 kHz, an output of 0.3 W, and a feed rate of 200 mm/s. In this way, the adhesive layer was singulated to produce a plurality of semiconductor chips with an adhesive piece, having a semiconductor chip and an adhesive piece.

Next, with a die separator (DDS2300, manufactured by DISCO Corporation), in order to reduce the adhesive force between the pressure-sensitive adhesive layer and the adhesive piece, the pressure-sensitive adhesive layer was irradiated with ultraviolet rays of an illuminance of 80 mW/cm² and an irradiation dose of 130 mJ/cm² from the base layer side to form a cured pressure-sensitive adhesive layer containing a cured product of the ultraviolet-curable pressure-sensitive adhesive, thereby obtaining a laminate (2) having a base layer, a cured pressure-sensitive adhesive layer, and a plurality of semiconductor chips with an adhesive piece in this order.

For the obtained laminate (2) having a plurality of semiconductor chips with an adhesive piece, excess semiconductor chips were removed using adhesive tape or the like so that the semiconductor chips with an adhesive piece were in alternating rows. Double-sided tape was applied to the surfaces of the remaining semiconductor chips, and a support substrate was laminated thereon. Thereafter, the dicing film was cut along the size of the support substrate from the back surface side, and the laminate having the support substrate was detached from the dicing ring. The dicing film in the locations where there were no semiconductor chips in the alternating rows was cut into a strip shape and removed, to produce a sample for edge peel strength measurement having a support substrate, double-sided tape, a semiconductor chip, an adhesive piece, a cured pressure-sensitive adhesive layer, and a base layer in this order.

Using the produced sample, the edge peel strength was measured using a desktop peel tester (EZ-Test, manufactured by Shimadzu Corporation). Only the strip-shaped dicing film was clamped in a jig so that the peel angle between the cured pressure-sensitive adhesive layer and the adhesive piece was 90°, and set in the tester. The feed rate was set to 60 mm/min, and during peeling, the sample was peeled while manually feeding the support substrate so that the peel angle between the cured pressure-sensitive adhesive layer and the adhesive piece was always 90°. The peel force corresponding to the edge portion of the obtained semiconductor chip was converted to a 20 mm width, and the edge peel strength was calculated. For a 4 mm×12 mm semiconductor chip with an adhesive piece, the peel strength in the direction perpendicular to the 4 mm side was designated as Ch1, and the peel strength in the direction parallel to the 4 mm side (the direction perpendicular to the 12 mm side) was designated as Ch2, and the average was calculated from the peaks for N=5 for each. This was measured for three samples each for Ch1 and Ch2, the average value of Ch1 and the average value of Ch2 were calculated, the sum of the average value of Ch1 and the average value of Ch2 was then determined, and this sum was divided by 2, and the resulting numerical value was taken as the value of the edge peel strength for each sample. The results are shown in Table 1.

TABLE 1

| | | Comp. | | | | | | | |
|---|---|---|---|---|---|---|---|---|---|
| | | Exam. 1 | Exam. 1 | Exam. 2 | Exam. 3 | Exam. 4 | Exam. 5 | Exam. 6 | Exam. 7 |
| (A) | (Aa-1) | 17.0 | 17.0 | 10.2 | 5.2 | 5.0 | 5.0 | 5.0 | 5.1 |
| | (Ab-1) | 1.0 | 16.2 | 1.0 | 1.0 | 6.5 | 25.0 | 5.7 | 8.8 |
| | (Ab-2) | 15.7 | 5.0 | 26.6 | 29.0 | 29.0 | 5.0 | 28.6 | 23.7 |
| (B) | (B-1) | 28.3 | 33.8 | 29.9 | 26.8 | 31.5 | 30.4 | 30.5 | 29.8 |
| (C) | (C-1) | 38.0 | 28.0 | 32.3 | 38.0 | 28.0 | 34.6 | 30.3 | 32.6 |
| (D) | (D-1) | — | — | — | — | — | — | — | — |
| (E) | (E-1) | 0.09 | 0.09 | 0.09 | 0.09 | 0.09 | 0.09 | 0.09 | 0.09 |
| (F) | (F-1) | 0.15 | 0.18 | 0.15 | 0.14 | 0.16 | 0.16 | 0.16 | 0.15 |

| | | | | | | | | |
|---|---|---|---|---|---|---|---|---|
| 25 °C Storage | 568 | 1366 | 1477 | 1755 | 1901 | 2233 | 1941 | 1712 |
| Modulus (MPa) | | | | | | | | |
| Minimum Melt | 2125 | 1112 | 1367 | 2487 | 988 | 2421 | 1345 | 1592 |
| Viscosity (Pa · s) | | | | | | | | |
| 100 °C Shear | 2602 | 1437 | 2002 | 3096 | 1358 | 2873 | 1841 | 2204 |
| Viscosity (Pa · s) | | | | | | | | |
| High-temperature | 7.0 | 96.0 | 38.0 | 12.4 | 108.6 | 48.6 | 93.2 | 82.2 |
| (150 °C) | | | | | | | | |
| Storage Modulus (MPa) | | | | | | | | |
| Edge Peel | 0.213 | 0.144 | 0.118 | 0.073 | 0.072 | 0.092 | 0.083 | 0.103 |
| Strength (N/20 mm) | | | | | | | | |

As shown in Table 1, the film-shaped adhesives of Examples 1 to 7, in which the storage modulus at 25° C. satisfies the predetermined requirements, had a sufficiently reduced edge peel strength compared to the film-shaped adhesive of Comparative Example 1, in which the storage modulus at 25° C. does not satisfy the predetermined requirements. From this result, it was confirmed that the film-shaped adhesive of the present disclosure has excellent peelability from the pressure-sensitive adhesive layer of a dicing film when applied to the adhesive layer of a dicing/die-bonding integrated film.

### REFERENCE SIGNS LIST

1 . . . film-shaped adhesive, 1A . . . adhesive layer, 2 . . . base layer, 3 . . . pressure-sensitive adhesive layer, 4 . . . dicing film, 10 . . . dicing/die-bonding integrated film, 11, 11a, 11b, 11c, 11d . . . semiconductor chip, 12 . . . support member, 13 . . . bonding wire, 14 . . . encapsulant, 15, 15a, 15b, 15c, 15d . . . adhesive member, 16 . . . terminal, 100, 110, 120 . . . semiconductor device.

1. A film-shaped adhesive comprising an epoxy resin, a phenolic resin, and an elastomer, and optionally further comprising an inorganic filler, wherein:
a content of the inorganic filler is from 0 to 5% by mass based on a total amount of the film-shaped adhesive; and
a storage modulus of the film-shaped adhesive at 25° C. is 1200 MPa or more.

2. The film-shaped adhesive according to claim 1, wherein:
a content of the elastomer is from 20 to 50% by mass based on the total amount of the film-shaped adhesive; and
a total content of the epoxy resin and the phenolic resin is from 45 to 80% by mass based on the total amount of the film-shaped adhesive.

3. The film-shaped adhesive according to claim 1, wherein:
the epoxy resin comprises a first epoxy resin having a softening point of 40° C. or less; and
a content of the first epoxy resin is from 2 to 20% by mass based on the total amount of the film-shaped adhesive.

4. The film-shaped adhesive according to claim 3, wherein:
the epoxy resin further comprises a second epoxy resin having a softening point of more than 40° C.; and
a softening point of the second epoxy resin is 120° C. or less.

5. The film-shaped adhesive according to claim 1, wherein a storage modulus at 150° C. of a cured product obtained by curing the film-shaped adhesive at 150° C. for 30 minutes is 10 MPa or more.

6. The film-shaped adhesive according to claim 1, wherein a thickness of the film-shaped adhesive is from 1 to 15 μm.

7. The film-shaped adhesive according to claim 1,
for use in a manufacturing process for a semiconductor device formed by stacking a plurality of semiconductor chips.

8. The film-shaped adhesive according to claim 7, wherein the semiconductor device is a 3D NAND memory.

9. A dicing/die-bonding integrated film, comprising in this order: a base layer; a pressure-sensitive adhesive layer; and an adhesive layer consisting of the film-shaped adhesive according to claim 1.

10. A semiconductor device, comprising:
a semiconductor chip;
a support member on which the semiconductor chip is mounted; and
a cured product of the film-shaped adhesive according to claim 1, disposed between the semiconductor chip and the support member and bonding the semiconductor chip and the support member.

11. The semiconductor device according to claim 10, further comprising a different semiconductor chip stacked on a surface of the semiconductor chip.

12. A method for manufacturing a semiconductor device, the method comprising:
laminating the adhesive layer of the dicing/die-bonding integrated film according to claim 9 onto a semiconductor wafer;
producing a plurality of singulated semiconductor chips with an adhesive piece by dicing the semiconductor wafer to which the adhesive layer has been laminated; and
bonding a first semiconductor chip with a first adhesive piece, which is one of the plurality of semiconductor chips with an adhesive piece, to a support member via the first adhesive piece.

13. The method according to claim 12, further comprising bonding a second semiconductor chip with a second adhesive piece, which is another of the plurality of semiconductor chips with an adhesive piece, onto a surface of the first semiconductor chip with the first adhesive piece bonded to the support member, via the second adhesive piece.

14. A method for manufacturing a semiconductor device, the method comprising:
providing a laminate comprising: the dicing/die-bonding integrated film according to claim 9; and a plurality of semiconductor chips provided on the adhesive layer of the dicing/die-bonding integrated film, the plurality of semiconductor chips being obtained by singulating a semiconductor wafer;
producing semiconductor chips with an adhesive piece by irradiating the adhesive layer with a laser through gaps between the plurality of semiconductor chips to singulate the adhesive layer; and
bonding a first semiconductor chip with a first adhesive piece, as one of the semiconductor chips with an adhesive piece, to a support member via the first adhesive piece.

15. The method according to claim 14, wherein the laminate is produced by a method including:
forming grooves along dicing lines on a circuit formation surface of the semiconductor wafer;
producing the plurality of semiconductor chips by grinding a back surface of the semiconductor wafer on which the grooves are formed, the back surface being on an opposite side to the circuit formation surface, to a depth that at least reaches the grooves; and
laminating the adhesive layer of the dicing/die-bonding integrated film onto back surfaces of the plurality of semiconductor chips.

16. The method according to claim 14, further comprising bonding a second semiconductor chip with a second adhesive piece, which is another of the semiconductor chips with an adhesive piece, onto a surface of the first semiconductor chip with the first adhesive piece bonded to the support member, via the second adhesive piece.

17. A method for manufacturing a semiconductor device, comprising bonding a first semiconductor chip and a support member, or the first semiconductor chip and a second semiconductor chip by interposing the film-shaped adhesive according to claim 1 between the first semiconductor chip and the support member, or between the first semiconductor chip and the second semiconductor chip.

18. A film-shaped adhesive comprising an epoxy resin, a phenolic resin, and an elastomer, wherein a storage modulus of the film-shaped adhesive at 25° C. is 1200 MPa or more.

19. The film-shaped adhesive according to claim 18, wherein the film-shaped adhesive further comprises an inorganic filler having a content that is less than or equal to 5% by mass based on a total amount of the film-shaped adhesive.

20. The film-shaped adhesive according to claim 18, wherein the film-shaped adhesive comprises a negligible amount, or none, of an inorganic filler.
